(19) United States
(12) Patent Application Publication
(10) Pub. No.: US 2024/0404725 A1
(43) Pub. Date: Dec. 5, 2024

(54) NOISE REDUCTION TOOL AND WIRE HARNESS

(71) Applicant: Yazaki Corporation, Tokyo (JP)

(72) Inventors: Itsuki Hasegawa, Shizuoka (JP); Kaori Usami, Shizuoka (JP); Jin Watanabe, Shizuoka (JP)

(73) Assignee: Yazaki Corporation, Tokyo (JP)

(21) Appl. No.: 18/799,073

(22) Filed: Aug. 9, 2024

Related U.S. Application Data
(63) Continuation of application No. PCT/JP2023/012057, filed on Mar. 25, 2023.

(30) Foreign Application Priority Data
Apr. 11, 2022 (JP) 2022-064953

(51) Int. Cl. H01B 7/00; H01B 7/18

(52) U.S. Cl. CPC H01B 7/0045; H01B 7/184

(57) ABSTRACT

A noise reduction tool includes a sheet-like or belt-like magnetic body that can be wound. In the magnetic body, electric wires, axial directions of which are aligned with a winding axis direction of a winding shape, are disposed side by side around an axis of a winding axis on one plane disposed on the inner side in the winding shape. For example, in the magnetic body, an adhesive to be bonded to the other plane is provided on one plane of an end portion located on the outermost side of both end portions extending along the winding axis direction in the winding shape.

### CROSS-REFERENCE TO RELATED APPLICATION

This application is a continuation application of International Application No. PCT/JP2023/012057 filed on Mar. 25, 2023 which claims the benefit of priority from Japanese Patent Application No. 2022-064953 filed on Apr. 11, 2022 and designating the U.S., the entire contents of which are incorporated herein by reference.

### BACKGROUND OF THE INVENTION

### 1. Field of the Invention

The present invention relates to a noise reduction tool and a wire harness.

### 2. Description of the Related Art

A noise reduction tool is a member made of a magnetic material and includes, as a component, a magnetic body attached to an electric wire, through which a noise current flows, to reduce emission to the outside of radiation noise emitted from the electric wire. For example, Japanese Patent Application Laid-open No. 2013-4354 described below discloses, as a noise countermeasure, a noise reduction tool in which a sheet-like magnetic body is wound around, in a grid shape, a plurality of electric wires bundled together and emission to the outside of radiation noise emitted from the electric wires, through which a noise current flows, among the plurality of wires is reduced by the magnetic body.

However, in the noise reduction tool of the related art, since one sheet-like magnetic body is wound around the plurality of electric wires bundled together, it is difficult to ensure intervals among the electric wires. That is, in this noise reduction tool, it is difficult to keep the distance between a certain electric wire through which the noise current flows and another electric wire that is likely to be affected by the radiation noise emitted from the electric wire.

### SUMMARY OF THE INVENTION

Therefore, an object of the present invention is to provide a noise reduction tool and a wire harness that can keep the distances among electric wires.

In order to achieve the above mentioned object, a noise reduction tool according to one aspect of the present invention includes: a sheet-like or belt-like magnetic body that can be wound, wherein in the magnetic body, electric wires, axial directions of which are aligned with a winding axis direction of a winding shape, are disposed side by side around an axis of a winding axis on one plane disposed on an inner side in the winding shape.

In order to achieve the above mentioned object, a wire harness according to another aspect of the present invention includes: a plurality of electric wires; and a noise reduction tool that reduces emission to an outside of radiation noise emitted from the respective electric wires, wherein the noise reduction tool includes a sheet-like or belt-like magnetic body that can be wound, and in the magnetic body, electric wires, axial directions of which are aligned with a winding axis direction of a winding shape, are disposed side by side around an axis of a winding axis on one plane disposed on an inner side in the winding shape.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram in which a wire harness to which a noise reduction tool in an embodiment is assembled is viewed in an axial direction;

FIG. 2 is a schematic diagram in which the wire harness to which the noise reduction tool in the embodiment is assembled is viewed from a side;

FIG. 3 is a perspective view schematically illustrating the noise reduction tool in the embodiment;

FIG. 4 is a plan view schematically illustrating the noise reduction tool in the embodiment before winding together with electric wires;

FIG. 5 is a schematic diagram in which the noise reduction tool in the embodiment is viewed from one plane side;

FIG. 6 is a schematic diagram in which another form of an adhesive in the noise reduction tool in the embodiment is viewed from one plane side;

FIG. 7 is a schematic diagram in which the wire harness to which the noise reduction tool in the modification is assembled is viewed in the axial direction;

FIG. 8 is a perspective view schematically illustrating a noise reduction tool in a modification;

FIG. 9 is a plan view schematically illustrating the noise reduction tool in the modification before winding together with electric wires;

FIG. 10 is a schematic diagram in which the noise reduction tool in the modification is viewed from one plane side; and

FIG. 11 is a schematic diagram in which another form of an adhesive in the noise reduction tool in the modification is viewed from one plane side.

### DETAILED DESCRIPTION OF THE PREFERRED EMBODIMENTS

An embodiment of a noise reduction tool and a wire harness according to the present invention is explained in detail below with reference to the drawings. Note that the present invention is not limited by the embodiment.

### Embodiment

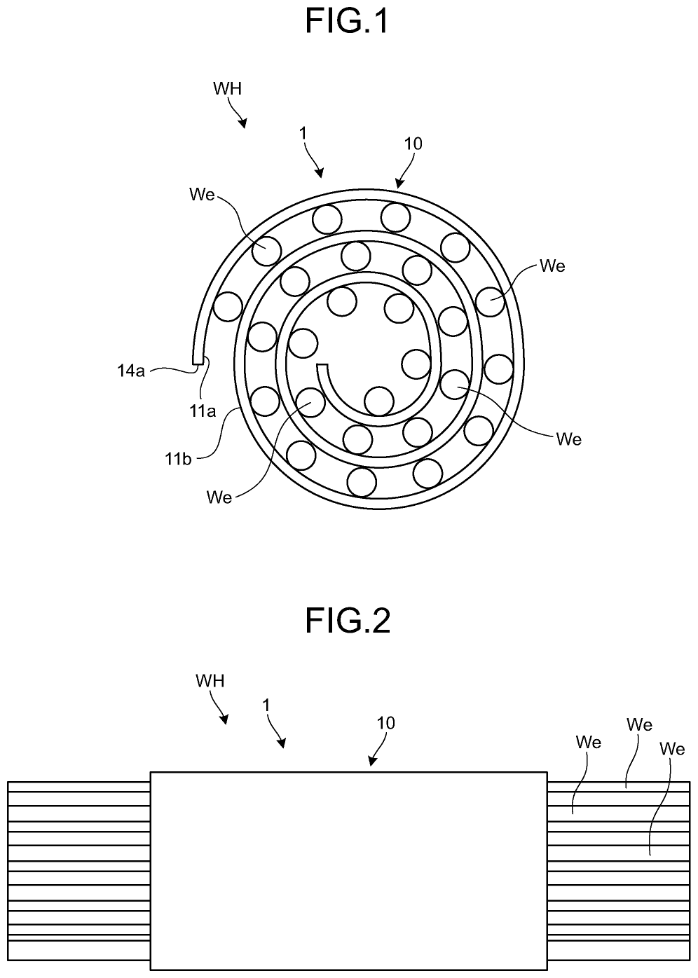

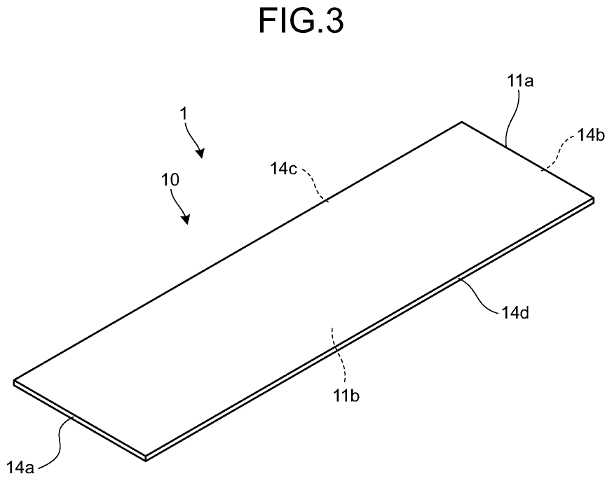

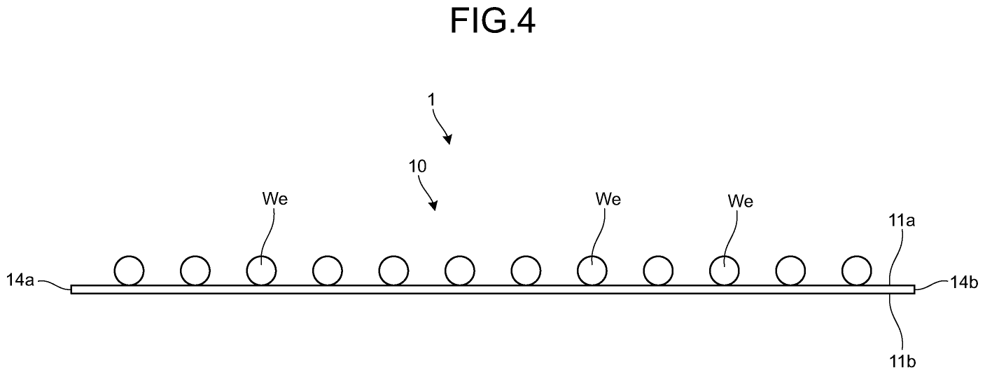

One of embodiments of the noise reduction tool and the wire harness according to the present invention is explained with reference to FIG. 1 to FIG. 6.

Reference numeral 1 illustrated in FIG. 1 to FIG. 6 denotes the noise reduction tool in the present embodiment. A noise reduction tool 1 is attached to a plurality of electric wires We, through which a noise current flows, to reduce emission to the outside of radiation noise emitted from the respective electric wires We and reduce the influence of the radiation noise among the respective electric wires We. Reference numeral WH illustrated in FIG. 1 and FIG. 2 denotes a wire harness in which the noise reduction tool 1 is assembled to the plurality of electric wires We. One or a plurality of noise reduction tools 1 are provided according to the length of the electric wires We.

The wire harness WH is mounted on an electric automobile (not illustrated) such as a BEV (Battery Electric Vehicle) or a PHEV (Plug-in Hybrid Electric Vehicle). As a specific example, the wire harness WH physically and electrically connects, between a secondary battery for driving and a secondary battery for auxiliary machine of the electric automobile, a DC/DC converter interposed between the secondary battery for driving and the secondary battery for auxiliary machine and the secondary battery for auxiliary machine. The wire harness WH is responsible for feeding electric power from the secondary battery for driving to the secondary battery for auxiliary machine when the secondary battery for auxiliary machine is charged.

The wire harness WH is used, for example, in a charging system (not illustrated) for charging the secondary battery for driving and the secondary battery for auxiliary machine of the electric automobile.

The charging system is configured as a charging system for normal charging or rapid charging irrespective of whether the charging system is for business use or home use. The charging system includes an external power supply, a charger main body to which electric power is supplied from the external power supply, and a charging cable with connector for feeding electric power from the charger main body to the vehicle side. The charging cable with connector is used by an operator in the power feeding and includes a charging cable provided with at least a plurality of power lines (electric wires We) and a charging connector attached to one terminal of the charging cable. Here, as the charging systems, there is also a charging system that performs charging control while performing communication between the vehicle and the charger main body at the time of the power feed. The charging cable in this case is also provided with a communication signal line responsible for the communication.

For example, when the charging system is configured as a charging system for rapid charging, a three-phase AC power supply is used as the external power supply and an AC/DC converter that converts an AC voltage of the three-phase AC power supply into a DC voltage is housed in a housing of the charger main body. The charging cable with connector in this case supplies electric power the conversion to the vehicle side.

The charging cable with connector is assembled to the charger main body in advance and may configure a charger in conjunction with the charger main body. The charging cable with connector is routed from the charger main body side to the vehicle side at the time of charging and physically and electrically connects the charging connector to a connector of the electric automobile (a vehicle-side connector).

On the other hand, the charging cable with connector is an independent component housed in a luggage room of the vehicle. A power supply-side connector may be attached to the other terminal of the charging cable. In this case, the charger main body configures the charger. When charging is performed, the charging cable with connector physically and electrically connect the power supply-side connector to the connector of the charger main body and physically and electrically connect the charging connector to the vehicle-side connector.

In this charging system, an internal charging cable for electrically connecting the AC/DC converter side and the charging cable side is provided in a housing of the charger main body. The internal charging cable includes at least a plurality of internal power lines (electric wires We). The AC/DC converter side and the charging cable side are electrically connected by the internal power lines. Accordingly, in the charging system, the wire harness WH in the present embodiment is obtained by attaching the noise reduction tool 1 to the plurality of internal power lines (the electric wires We) in the internal charging cable. When the communication described above is performed in the charging, an internal communication signal line is also provided in the internal charging cable. In this charging system, the wire harness WH in the present embodiment is obtained by attaching the noise reduction tool 1 to the plurality of power lines (the electric wires We) in the charging cable of the charging cable with connector.

In the following explanation, the noise reduction tool 1 and the wire harness WH in the present embodiment are specifically explained.

The noise reduction tool 1 includes a sheet-like or belt-like magnetic body 10 that can be wound (FIG. 1 to FIG. 6). The magnetic body 10 is formed of a ferromagnetic material to have flexibility. Ferrite or the like is used as the ferromagnetic material.

In the magnetic body 10, the electric wires We, axial directions of which are aligned with a winding axis direction of a winding shape, are disposed side by side around the axis of a winding axis on one plane 11a disposed on the inner side in the winding shape (FIG. 1).

In the noise reduction tool 1, the plurality of electric wires We, axial directions of which are aligned, are arranged one by one along one plane 11a in a direction orthogonal to the axial direction on one plane 11a of the sheet-like or belt-like magnetic body 10. In the noise reduction tool 1, the magnetic body 10 is wound in a grid shape together with the respective electric wires We with the one plane 11a facing inward (FIG. 1). Accordingly, in the noise reduction tool 1, the magnetic body 10 is interposed between the electric wires We adjacent to each other in the radial direction of the winding shape and an interval can be provided between the electric wires We. Accordingly, the noise reduction tool 1 can not only reduce emission to the outside of radiation noise emitted from the respective electric wires We but also reduce the influence of the radiation noise between the electric wires We adjacent to each other in the radial direction.

Here, in the noise reduction tool 1, when the respective electric wires We are viewed around the axis of the winding axis, the interval between the electric wires We adjacent to each other around the axis is short in one case and is long in another case. Accordingly, in the noise reduction tool 1, it is desirable to arrange the plurality of electric wires We, the axial directions of which are aligned, one by one at intervals in the direction orthogonal to the axial direction on one plane 11a of the magnetic body 10. At that time, in the noise reduction tool 1, in order to keep the interval between the electric wires We, for example, it is desirable that the respective electric wires We are stuck to the one plane 11a of the magnetic body 10 via an adhesive (for example, an adhesive 22 explained below) provided on the one plane 11a. In the noise reduction tool 1, the magnetic body 10 is wound in a grid shape together with the respective electric wires We with one plane 11a facing inward (FIG. 1). Accordingly, in the noise reduction tool 1, the magnetic body 10 is interposed between the electric wires We adjacent to each other in the radial direction of the winding shape and an interval can be provided between the electric wires We. Further, in the noise reduction tool 1, since the plurality of electric wires We are disposed side by side at intervals from one another around the axis of the winding axis, it is possible to provide an interval between the electric wires We adjacent to each other around the axis. For that reason, the noise reduction tool 1 can not only reduce emission to the outside of radiation noise emitted from the respective electric wires We but also reduce the influence of the radiation noise between the electric wires We adjacent each other in the radial direction and reduce the influence of the radiation noise between the electric wires We adjacent each other around the axis of the winding axis.

In order to maintain the winding shape of the magnetic body 10, the noise reduction tool 1 may include, for example, one or a plurality of binding bands to be wound around the magnetic body 10 having the winding shape according to the length in the winding axis direction (not illustrated).

In order to keep the winding shape of the magnetic body 10, the noise reduction tool 1 may use an adhesive instead of the binding band or together with the binding band.

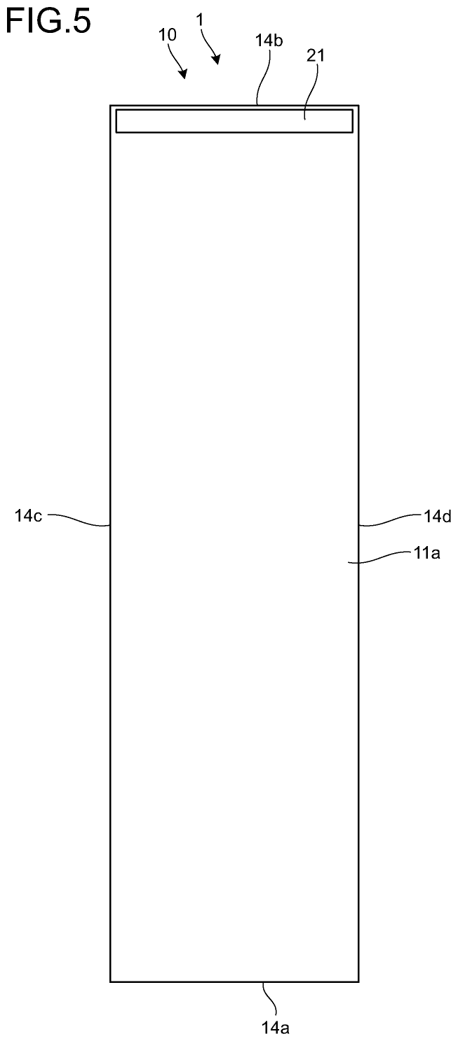

For example, in the noise reduction tool 1 illustrated in FIG. 5, an adhesive 21 to be bonded to the other plane 11b of the magnetic body 10 is provided on one plane 11a of an end portion 14b located at the outermost side of both end portions 14a and 14b in the winding axis direction in the winding shape of the magnetic body 10.

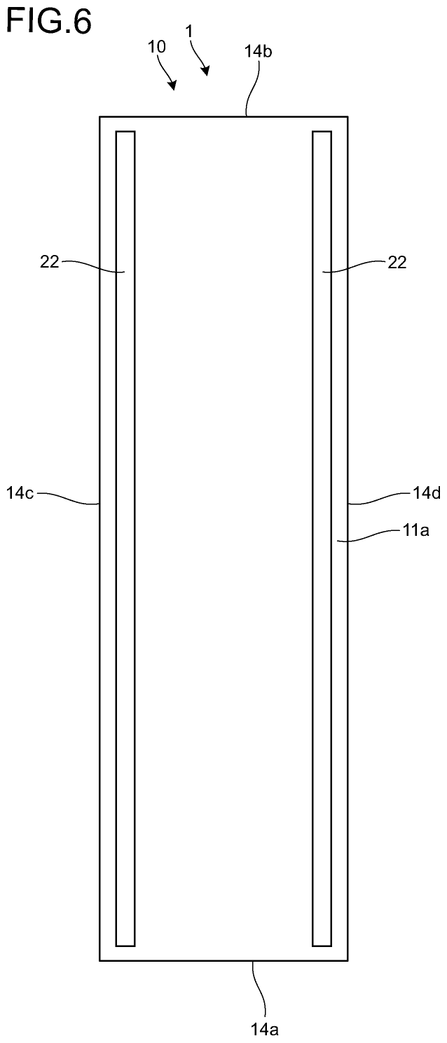

For example, in the noise reduction tool 1 illustrated in FIG. 6, an adhesive 22 to be bonded to at least the other plane 11b of the magnetic body 10 is provided on one plane 11a of the respective end portions 14c and 14d orthogonal to the winding axis direction in the winding shape in the magnetic body 10. Accordingly, the noise reduction tool 1 can be given a function of preventing positional deviation of the electric wires We with respect to one plane 11a and a holding function by the adhesive 22. The noise reduction tool 1 can improve, with the holding function, assembling workability until winding work for the sheet-like or belt-like magnetic body 10 is completed.

As described above, the noise reduction tool 1 in the present embodiment can reduce emission to the outside of radiation noise emitted from the electric wires We. The noise reduction tool 1 can keep the distances among the respective electric wires We. Accordingly, the noise reduction tool 1 can reduce the influence of the radiation noise among the respective electric wires We compared with when the sheet-like magnetic body is wound in a grid-like shape around the plurality of electric wires We bundled together. Furthermore, even if the electric wires We having different electric wire diameters and the electric wires We having different lengths are mixed, the noise reduction tool 1 can be applied to the plurality of electric wires We. The wire harness WH in the present embodiment includes the noise reduction tool 1 and can achieve the same effects as the effects obtained by the noise reduction tool 1.

### Modification

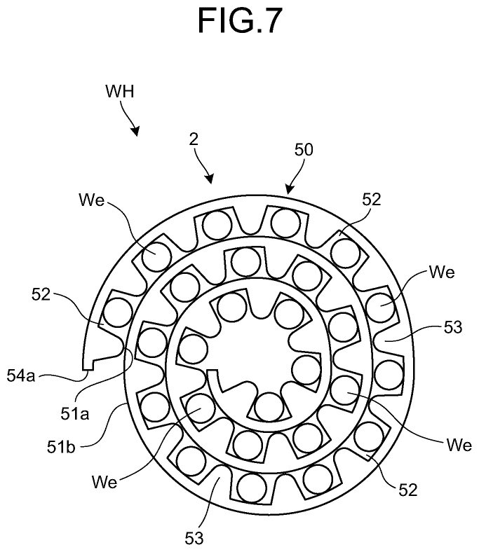

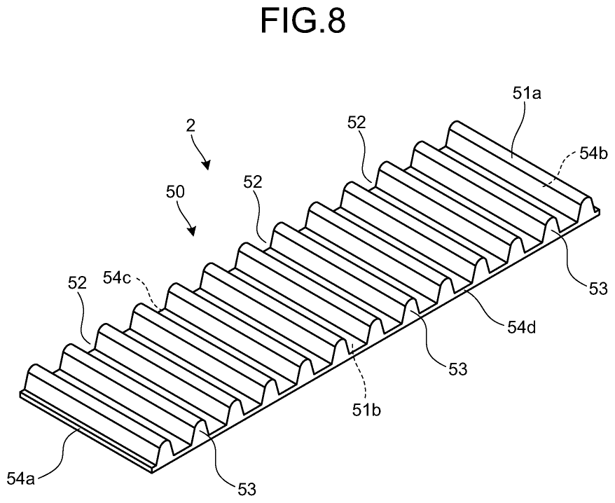

Reference numeral 2 illustrated in FIG. 7 to FIG. 11 denotes a noise reduction tool in a modification. Like the noise reduction tool 1 in the embodiment explained above, a noise reduction tool 2 is attached to the plurality of electric wires We, through which noise current flows, to reduce emission to the outside of radiation noise emitted from the respective electric wire We and reduce the influence of the radiation noise among the respective electric wires We. In the wire harness WH in the present modification, the noise reduction tool 2 is assembled to the plurality of electric wires We. One or a plurality of noise reduction tools 2 are provided according to the length of the electric wires We.

The noise reduction tool 2 in the present modification includes a sheet-like or belt-like magnetic body 50 that can be wound (FIG. 7 to FIG. 11). Like the magnetic body 10 in the embodiment, the magnetic body 50 is formed of a ferromagnetic material such as ferrite to have flexibility and is wound in a grid shape together with the plurality of electric wires We.

The magnetic body 50 includes, on one plane 51a having a winding shape and disposed on the inner side, grooves 52 for each of the electric wires We, the grooves 52 being capable of housing the electric wires We one by one with the axial direction aligned with the winding axis direction of the winding shape (FIG. 7 to FIG. 11).

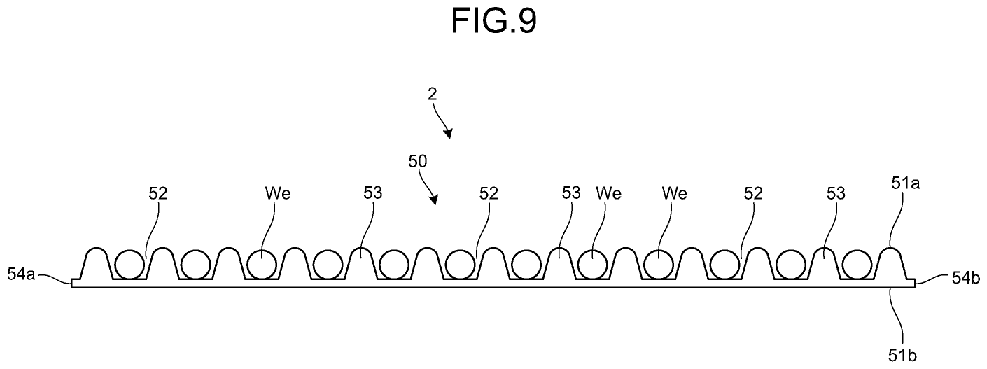

In the noise reduction tool 2, the electric wires We are housed one by one in the sheet-like or belt-like magnetic body 50 for each of the grooves 52 (FIG. 9). In the noise reduction tool 2, the magnetic body 50 is wound in a grid shape together with the respective electric wires We with one plane 51a facing inward (FIG. 6). Accordingly, in the noise reduction tool 2, intervals can be provided among the respective electric wires We. Therefore, the noise reduction tool 2 can not only reduce emission to the outside of radiation noise emitted from the respective electric wires We but also reduce the influence of the radiation noise among the respective electric wires We.

Further, in the noise reduction tool 2, since all the grooves 52 (groove widths and groove depths) are formed in an equal shape, it is not necessary to specify housing places of the electric wires We in the grooves 52 as long as the electric wires We have the same electric wire diameter. Therefore, assembling workability between the magnetic body 50 and the electric wires We can be improved.

Here, in the magnetic body 50, the groove depth of the grooves 52 is desirably set larger than the electric wire diameter of the electric wires We. Accordingly, in the magnetic body 50, crest sections 53 higher than the electric wire diameter are interposed among the respective electric wires We housed in the grooves 52 adjacent to one another (FIG. 7 to FIG. 9). Therefore, the noise reduction tool 2 can further reduce the influence of the radiation noise among the respective electric wires We.

The grooves 52 may be formed in a shape of fitting the electric wires We therein to be clamped between the crest sections 53 on both the sides. Accordingly, in the noise reduction tool 2, by fitting the electric wires We in the grooves 52, the electric wires We can be held while being housed in the grooves 52 until winding work for the sheet-like or belt-like magnetic body 50 is completed. Accordingly, the noise reduction tool 2 can improve assembly workability until the winding work is completed.

In order to keep the winding shape of the magnetic body 50, the noise reduction tool 2 may include, according to the length in the winding axis direction, for example, one or a plurality of binding bands to be wound around the magnetic body 50 having the winding shape (not illustrated).

In order to keep the winding shape of the magnetic body 50, the noise reduction tool 2 may use an adhesive instead of the binding band or together with the binding band.

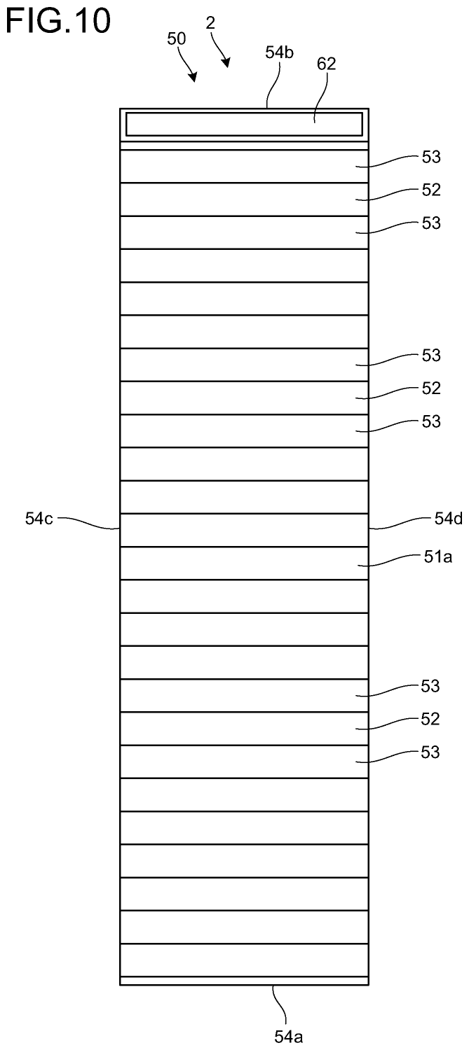

For example, in the noise reduction tool 2 illustrated in FIG. 10, an adhesive 61 to be bonded to the other plane 51b of the magnetic body 10 is provided on one plane 51a of an end portion 54b located at the outermost side of both end portions 54a and 54b in the winding axis direction in the winding shape of the magnetic body 50.

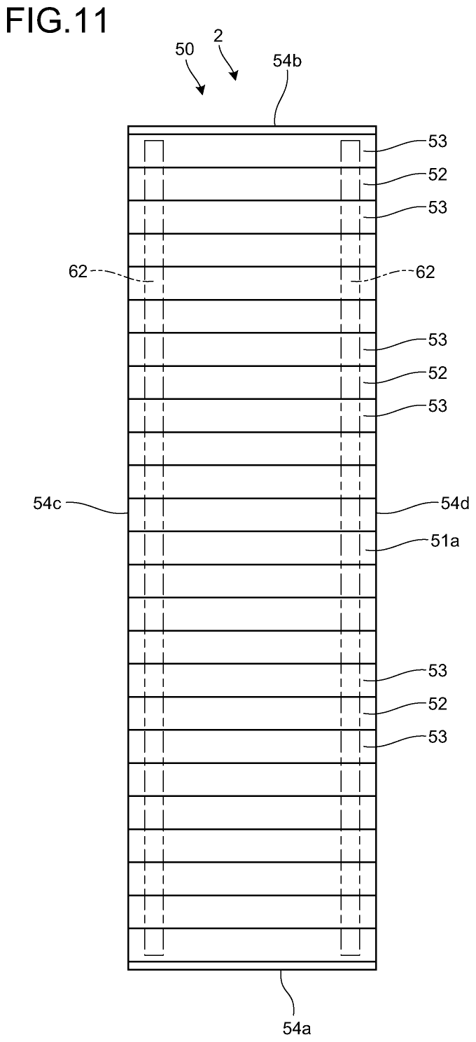

For example, in the noise reduction tool 2 illustrated in FIG. 11, an adhesive 62 to be bonded to at least the other plane 51b of the magnetic body 50 is provided on one plane 51a of respective end portions 54c and 54d orthogonal to the winding axis direction in the winding shape of the magnetic body 50. In the magnetic body 50, by providing the adhesive 62 up to the wall surfaces in the grooves 52, the electric wires We can be held by the adhesive 62 in the grooves 52. Accordingly, the noise reduction tool 2 can be given a function of preventing positional deviation of the electric wires We with respect to the grooves 52 and a holding function by the adhesive 62 in the grooves 52. With the holding function, the noise reduction tool 2 can improve assembly workability until the winding work for the sheet-like or belt-like magnetic body 50 is completed even if the electric wires We are not fit in the grooves 52. For convenience of illustration, the adhesive 62 is indicated by an alternate long and short dash line in the drawings.

As explained above, the noise reduction tool 2 in the present modification can reduce emission to the outside of radiation noise emitted from the respective electric wires We. The noise reduction tool 2 can keep the distances among the respective electric wires We with the grooves 52. Accordingly, the noise reduction tool 2 can reduce the influence of the radiation noise among the respective electric wires We compared with when the sheet-like magnetic body is wound in a grid-like shape around the plurality of electric wires We bundled together. Furthermore, as long as the electric wires We have an electric wire diameter that can be housed in the grooves 52, the noise reduction tool 2 can be applied to the plurality of electric wires We even if the electric wires We having different electric wire diameters or the electric wires We having different lengths are mixed. The wire harness WH in the present modification includes the noise reduction tool 2 and can achieve the same effects as the effects obtained by the noise reduction tool 2.

Since the noise reduction tool 1 and the wire harness WH in the embodiment and the noise reduction tool 2 and the wire harness WH in the modification explained above can obtain the effects with a simple and inexpensive configuration, application to the electric automobile and the charging system described above (irrespective of whether the electric automobile and the charging system are for normal charging or rapid charging) contributes to the spread of the electric automobile and the charging system.

Further, a possibility of occurrence of noise is higher in the charging system configured as the charging system for rapid charging than in the charging system configured as the charging system for normal charging. Therefore, the noise reduction tool 1 and the wire harness WH in the embodiment and the noise reduction tool 2 and the wire harness WH in the modification are particularly useful in a charging system for rapid charging and an electric automobile using the charging system and capable of rapid charging.

The noise reduction tool and the wire harness according to the present embodiment can reduce emission to the outside of radiation noise emitted from the respective electric wires. Since the noise reduction tool and the wire harness can keep the longer distances among the respective electric wires than the noise reduction tool and the wire harness of the related art, the influence of the radiation noise among the electric wires can be reduced.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A noise reduction tool comprising:
a sheet-like or belt-like magnetic body that can be wound, wherein
in the magnetic body, electric wires, axial directions of which are aligned with a winding axis direction of a winding shape, are disposed side by side around an axis of a winding axis on one plane disposed on an inner side in the winding shape,
an adhesive to be bonded to at least another plane of the magnetic body is provided on the one plane of the respective end portions orthogonal to the winding axis direction in the winding shape in the magnetic body, and
the adhesive adheres the plurality of electric wires aligned one by one at intervals in a direction orthogonal to the axial direction and keeps the interval between the electric wires.

2. A wire harness comprising:
a plurality of electric wires; and
a noise reduction tool that reduces emission to an outside of radiation noise emitted from the respective electric wires, wherein
the noise reduction tool includes a sheet-like or belt-like magnetic body that can be wound,
in the magnetic body, electric wires, axial directions of which are aligned with a winding axis direction of a winding shape, are disposed side by side around an axis of a winding axis on one plane disposed on an inner side in the winding shape,
an adhesive to be bonded to at least another plane of the magnetic body is provided on the one plane of the respective end portions orthogonal to the winding axis direction in the winding shape in the magnetic body, and
the adhesive adheres the plurality of electric wires aligned one by one at intervals in a direction orthogonal to the axial direction and keeps the interval between the electric wires.
